(19) United States
(12) Patent Application Publication
(10) Pub. No.: US 2024/0201596 A1
(43) Pub. Date: Jun. 20, 2024

(54) Methods and related systems for depositing EUV sensitive films

(71) Applicant: ASM IP Holding B.V., Almere (NL)

(72) Inventors: Kishan Ashokbhai Patel, Leuven (BE); Yoann Tomczak, Leuven (BE); Charles Dezelah, Helsinki (FI); Ivan Zyulkov, Brussels (BE); David Kurt De Roest, Leuven (BE); Michael Givens, Oud-Heverlee (BE); Daniele Piumi, Etterbeek (BE)

(21) Appl. No.: 18/528,314

(22) Filed: Dec. 4, 2023

Related U.S. Application Data
(60) Provisional application No. 63/431,337, filed on Dec. 9, 2022.

(51) Int. Cl. G03F 7/16; G03F 7/004

(52) U.S. Cl. CPC G03F 7/167; G03F 7/0045; G03F 7/165

(57) ABSTRACT

Methods and related systems for forming an EUV sensitive film on a substrate. The methods comprise executing a plurality of deposition cycles. A deposition cycle comprises a first deposition pulse and a second deposition pulse. The first precursor pulse comprises exposing the substrate to a first precursor. The first precursor comprises a metal precursor. The second precursor pulse comprises exposing the substrate to a second precursor. The second precursor comprises a heterocyclic organic compound.

### CROSS-REFERENCE TO RELATED APPLICATIONS

The present disclosure claims priority to and the benefit of U.S. Provisional Application No. 63/431,337, filed Dec. 9, 2022, the entirety of which is incorporated by reference herein.

### FIELD OF INVENTION

The present disclosure generally relates to method of forming structures suitable for use in the manufacture of electronic devices. More particularly, the disclosure relates to methods of forming radiation-sensitive, patternable materials on a surface of a substrate and to reactor systems for performing the methods.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it generally becomes increasingly desirable to form features with smaller dimensions.

Photoresist is often used to pattern a surface of a substrate prior to etching. A pattern can be formed in the photoresist by applying a layer of photoresist to a surface of the substrate, masking a surface of the photoresist, exposing an unmasked portion of the photoresist to radiation, such as ultraviolet light, and developing a portion of the photoresist to remove the unmasked or masked portion of the photoresist, while leaving the other of the unmasked and masked portion of the photoresist on the substrate surface.

The photoresist is typically spin-coated onto the surface of the substrate using a liquid solution. While such techniques work relatively well for several applications, spin-on coating techniques may not provide desired (relatively low) thickness or thickness uniformity of the photoresist on the substrate surface. Accordingly, improved methods of forming patternable material on the surface of the substrate are desired.

Extreme ultraviolet (EUV) lithography technique is becoming a mainstream method for the fabrication of semiconductor devices with the critical dimensions below 20 nm. The broad consensus on this direction has triggered a dramatic increase of interest on resist materials of high sensitivity especially designed for use with the EUV tool in order to meet the strict requirements needed for overcoming the source brightness issues and securing the cost efficiency of the technology. Another limitation with EUV lithography is the penetration depth, furthermore with next generation high numerical aperture EUV tool the depth of penetration of the beam will be sub-20-nm. This requires that the resist thickness should be less than the penetration depth. Depositing uniform resist film with sub-20-nm thickness by conventional spin-coating method will be very challenging. As well as such thin films do not provide sufficient etch resistance for the pattern transfer by dry/wet etch.

Any discussion of problems and solutions set forth in this section has been included in this disclosure solely for the purpose of providing a context for the present disclosure and 2 should not be taken as an admission that any or all of the discussion was known at the time the invention was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of forming radiation-sensitive, patternable material on a surface of a substrate and to systems for forming the material. While the ways in which various embodiments of the present disclosure address drawbacks of prior methods are discussed in more detail below, in general, various embodiments of the disclosure provide method of forming relatively thin, uniform radiation-sensitive, patternable material using deposition techniques.

In accordance with exemplary embodiments of the disclosure, a method for forming an extreme ultraviolet (EUV) sensitive film on a substrate by a cyclic deposition process is provided. The method for forming the film can include providing a substrate in a reactor chamber; and, executing a cyclical deposition process. The cyclical deposition process may comprise the steps of providing a metal precursor into the reactor chamber in vapor phase; and providing a heterocyclic organic precursor into the reactor chamber in vapor phase, to form a EUV sensitive film on a substrate.

In accordance with other exemplary embodiments of the disclosure, a reactor system is provided. An exemplary system includes one or more reaction chambers constructed to hold a substrate; a metal precursor vessel constructed and arranged to contain and evaporate a metal precursor; and a heterocyclic organic precursor vessel constructed and arranged to contain and evaporate a heterocyclic organic precursor. Exemplary systems can further include a controller configured to control gas flow of the metal precursor and heterocyclic organic precursor into the one or more reaction chambers to form a film on a substrate comprised in the reaction chamber by means of a method according to one or methods or method steps described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIGS. 1A-C illustrate methods in accordance with exemplary embodiments of the disclosure.

FIG. 2 illustrates a system in accordance with exemplary embodiment of the disclosure.

FIG. 3 illustrates schematically an embodiment of a method of forming an EUV sensitive film in accordance with exemplary embodiments of the disclosure.

FIG. 4 illustrates schematically an embodiment of a method of forming an EUV sensitive film in accordance with exemplary embodiments of the disclosure.

FIG. 5 illustrates an exemplary embodiment of a method of forming a pattern on a substrate.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of forming an extreme ultraviolet (EUV) sensitive film on a substrate by a cyclic deposition process is provided. The method for forming the film can include providing a substrate in a reactor chamber; and, executing a cyclical deposition process. The cyclical deposition process may comprise the steps of providing a metal precursor into the reactor chamber in vapor phase; and providing a heterocyclic organic precursor into the reactor chamber in vapor phase, to form a EUV sensitive film on a substrate.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a plate, or a workpiece. Substrates in the form of a plate may include wafers in various shapes and sizes. Substrates may be made from semiconductor materials, including, for example, in silicon, silicon germanium, silicon oxide, gallium arsenide, gallium nitride and silicon carbide. In some cases, a substrate can include one or more of an underlayer, an absorber layer, and a hard mask layer at or near the surface of the substrate prior to forming the radiation-sensitive, patternable material on a surface of a substrate.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a film, a roll, a foil, or a flexible material. Continuous substrates may also comprise carriers or sheets upon which non-continuous substrates are mounted.

In some embodiments, film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, gas may include material that is a gas at normal temperature and pressure, a vaporized solid and/or a vaporized liquid, and may be constituted by a single gas or a mixture of gases, depending on the context. In some cases, such as in the context of deposition of material, the term precursor can refer to a compound that participates in the chemical reaction that produces another compound, and particularly to a compound that constitutes a film matrix or a main skeleton of a film. In some cases, the terms precursor and reactant can be used interchangeably. The term inert gas refers to a gas that does not take part in a chemical reaction to an appreciable extent and/or an otherwise relatively non-reactive gas from which excited species can be formed (e.g., using a plasma) to excite or interact with a precursor, but unlike a reactant, it may not become a part of a film matrix to an appreciable extent.

The term chemical vapor deposition can refer to a gas-phase process in which a precursor and often a reactant are provided to and/or are within a reaction chamber for an overlapping period of time. In some cases, a precursor alone can react, for example with a substrate surface or in a gas phase, to form a material on the substrate surface. In some cases, a precursor can react with activated species formed using a noble gas. In some cases, the precursor and a reactant (e.g., excited species derived from either) can react to form the material on the substrate surface.

The term cyclic deposition process or cyclical deposition process may refer to the sequential introduction of precursors (and/or reactants) into a reaction chamber to deposit a layer over a substrate and includes processing techniques, such as atomic layer deposition (ALD), molecular layer deposition (MLD), cyclical chemical vapor deposition (cyclical CVD), and hybrid cyclical deposition processes that include an ALD component and a cyclical CVD component. A cyclical deposition process can include plasma-enhanced processes, such as pulsed plasma-enhanced chemical vapor deposition processes.

The term atomic layer deposition may refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, and the like.

The term molecular layer deposition may refer to a vapor deposition process in which deposition cycles, typically a plurality of consecutive deposition cycles, are conducted in a process chamber to form layers comprising organic molecules. The term molecular layer deposition, as used herein, is also meant to include processes designated by related terms, atomic layer deposition (ALD), such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es).

EUV-sensitive layers formed according to methods by a cyclic deposition process is provided. The method for forming the film can include providing a substrate in a reactor chamber; and, executing a cyclical deposition process. The cyclical deposition process may comprise the steps of providing a metal precursor into the reactor chamber in vapor phase; and providing a heterocyclic organic precursor into the reactor chamber in vapor phase, to form a EUV sensitive film on a substrate.

In this disclosure, continuously can refer to one or more of without breaking a vacuum, without interruption as a timeline, without any material intervening step, without changing one or more conditions, immediately thereafter, as a next step, or without an intervening discrete physical or chemical structure or layer between two structures or layers in some embodiments. For example, a reactant and/or an inert or noble gas can be supplied continuously during two or more steps and/or cycles of a method.

In this disclosure, the term “about” can refer to the exact value or 10% more or less than the value.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

Described herein is a method of forming an EUV-sensitive layer, i.e., a layer which is sensitive to extreme ultraviolet light. Extreme ultraviolet light can be described as electromagnetic radiation having a wavelength from at least 1 nm to at most 50 nm. Alternatively, extreme ultraviolet light can be called low-wavelength ultraviolet light or low-energy x-rays.

According to some embodiments of the disclosure, there is described a method for forming an extreme ultraviolet (EUV) sensitive film on a substrate by a cyclic deposition process. The method comprises steps of providing a substrate in a reactor chamber; providing a metal precursor into the reactor chamber in vapor phase; and providing a heterocyclic organic precursor into the reactor chamber in vapor phase; to form a EUV sensitive film on a substrate. According to one embodiment the metal precursor is provided into the reactor before the heterocyclic organic precursor. According to one embodiment the heterocyclic organic precursor is provided into the reactor before the metal precursor. According to one embodiment the heterocyclic organic precursor and the metal precursor are provided into the reactor at least partially overlapping.

In some embodiments, a method of forming an EUV-sensitive layer as described herein can be categorized as an atomic layer deposition (ALD) process, or as a molecular layer deposition (MLD) process. Such an EUV-sensitive layer can, after a patterning step, be employed as a mask for a subsequent etch step. Additionally or alternatively, and after a patterning step, such an EUV-sensitive layer can be employed to locally and selectively grow further material layers on one of exposed and unexposed areas versus the other.

EUV-sensitive layers formed according to methods as described herein have several advantages over EUV-sensitive layers which are formed using liquid formulations. For example, the present EUV-sensitive layers can have equal or improved EUV sensitivity at lower thicknesses, they can offer better resolution, and they can offer process simplifications. For example, an EUV-sensitive layer formed according to a method as described herein can be directly formed on a substrate, without necessarily requiring the presence of an intermediate glue layer.

According to one embodiment, the organic ring in the heterocyclic organic precursor is selected from the group consisting of cyclic anhydrate, cyclic carbonate and cyclic azasilane.

According to one embodiment, the heterocyclic organic precursor comprises a carbon-carbon double bond or a carbon-carbon single bond in the ring.

According to one embodiment the organic ring comprises a 5 or 6-membered ring.

According to one embodiment the cyclic carboxylic acid anhydride can have a general formula of:

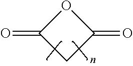

wherein the value of n is an integer from 1 to 6.

According to one embodiment the cyclic carbonate can have a general formula of:

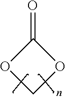

wherein the value of n is an integer from 1 to 6.

According to one embodiment the cyclic azasilane can have a general formula of:

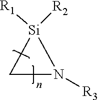

wherein the value of n is an integer from 1 to 6; R₁, R₂ and R₃ can be independently any C1-C6 alkyl, alkoxy, or aminoalkyl group.

According to one embodiment the cyclic carboxylic acid anhydride can have a general formula of:

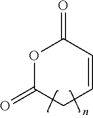

wherein the value of n is an integer from 0 to 5; the position of the carbon-carbon double bond in the drawings is for illustrative purposes and may occupy other sites in the ring. In some embodiments, the carbon-carbon double bond can be separated from the anhydride group by 0, 1, 2, or 3 carbon atoms.

According to one embodiment the cyclic carbonate can have a general formula of:

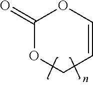

wherein the value of n is an integer from 0 to 5; the position of the carbon-carbon double bond in the drawings is for illustrative purposes and may occupy other sites in the ring.

According to one embodiment the cyclic azasilane can have a general formula of:

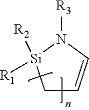

wherein the value of n is an integer from 0 to 5; the position of the carbon-carbon double bond in the drawings is for illustrative purposes and may occupy other sites in the ring; R₁, R₂ and R₃ can be independently any C1-C6 alkyl, alkoxy, or aminoalkyl group.

According to one embodiment, the heterocyclic organic precursor may be a cyclic carboxylic acid anhydride selected from the group consisting of malonic anhydride, succinic anhydride, maleic anhydride, glutaric anhydride, gluaconic anhydride, adipic anhydride, 3,6-dihydro-2,7-oxepindione, phthalic anhydride, pyromellitic dianhydride and 3-oxabicyclo[3.1.0.]hexane-2,4-dione. According to one embodiment the cyclic carboxylic acid anhydride may be maleic anhydride.

According to one embodiment, the heterocyclic organic precursor may be a cyclic carbonate selected from the group consisting of ethylene carbonate, trimethylene carbonate, tetramethylene carbonate, vinylene carbonate, dehydrotrimethylene carbonate and 4,7-dihydro-1,3-dioxepin-2-one.

According to one embodiment, the heterocyclic organic precursor may be a cyclic azasilane selected from the group consisting of N-n-butyl-aza-2,2-dimethoxysilacyclopentane, N-(2-aminoethyl)-2,2,4-trimethyl-1-aza-2-silacyclopentane, (N,N-dimethylaminopropyl)-aza-2-methyl-2-methoxysilacyclopentane, 2,2-dimethoxy-1,6-diaza-2-silacyclooctane, N-methyl-aza-2,2,4-trimethylsilacyclopentane and N-allyl-aza-2,2-demethoxysilacyclopentane.

According to one embodiment, the metal precursor comprises a metal atom selected from the group consisting of Sn, Ti, Zn, Zr, Al, Sb, Te, Ge, In, Si and Hf.

According to one embodiment, the metal precursor comprises a ligand selected from the group consisting of alkyl, heteroleptic alkyl, tetraneopentyl, dialkyl, amido, alkoxide, alkylamido, halide and amidinate. According to one embodiment the ligand comprises a halide when a coreactant is also provided into the reaction chamber as the halide may not react with an anhydride but may react with molecules comprising a Si—N bond, such as azasilane.

According to one embodiment, the process further comprises providing a coreactant into the reactor chamber in vapor phase. Without the invention being bound to any particular theory or mode of operation, it is believed that such a coreactant can added to the process when the metal precursor comprises a ligand which does not have good ring opening properties, such as halides, to enhance the ring opening properties of the heterocyclic organic precursor. According to one embodiment, the coreactant is provided into the reactor chamber after the metal precursor. In another embodiment, the coreactant is provided into the reactor chamber after the heterocyclic organic precursor. In another embodiment, the coreactant is provided to the reactor chamber before the metal precursor and the heterocyclic organic precursor.

According to one embodiment, the coreactant is chosen from the group consisting of water, ammonia, homobifunctional organic molecule and heterobifunctional organic molecule.

According to one embodiment, the homobifunctional organic molecule and heterobifunctional molecule comprise at least one molecule selected from the group consisting of alcohol, amine, thiol, carboxylic acid and carboxylic acid halide.

According to one embodiment, the homobifunctional organic molecule and heterobifunctional molecule are molecules with two functional groups. The two functional groups in the bifunctional units are connected by alkyl chain consisting of 1-8 carbon atoms.

According to one embodiment, the two functional groups in the homobifunctional organic molecule and the heterobifunctional organic molecule are attached to a benzene ring.

According to one embodiment, the two functional groups in the homobifunctional organic molecule and the heterobifunctional organic molecule are attached separate carbon atoms on a cycloalkane comprising from 3 to 8 carbon atoms.

Without the invention being bound by any particular theory or mode of operation, it is believed that by having a ring-containing heterocyclic organic compound precursor combined with a metal precursor, these ring-containing heterocyclic organic compounds undergo ring opening reaction when in contact with various surface terminated groups and together with the metal precursor form an organometallic framework. The double bonds and conjugations from the organic compound may be an EUV sensitive component of the film, while different metal centers from metal precursors may be an EUV absorbing component of the film. In other words, upon EUV exposure, the metal center absorbs the radiation and then provides energy to initiate either cross-linking or dissociation of the double bonds of the organic compound. Both mechanisms can provide different kind of film properties, i.e., negative or positive tone resist depending on which organic coreactant and metal precursor combination is used with particular development methods, i.e., wet and dry development.

According to another aspect of the current disclosure, there is provided a deposition assembly for depositing an EUV sensitive film a substrate. The assembly comprises one or more reaction chambers constructed and arranged to hold the substrate, a precursor injector system constructed and arranged to provide a metal precursor and a heterocyclic organic precursor into the reaction chamber in a vapor phase. The deposition assembly further comprises a first precursor vessel constructed and arranged to contain and evaporate a metal precursor. The deposition assembly further comprises a second precursor vessel constructed and arranged to contain and evaporate a heterocyclic organic precursor. The deposition assembly is constructed and arranged to provide the metal precursor and the heterocyclic organic precursor via the precursor injector system to the reaction chamber to deposit an EUV sensitive film on the substrate.

In some embodiments, the assembly further comprises a coreactant vessel constructed and arranged to contain and evaporate a coreactant as described in the above disclosure, a coreactant input constructed and arranged to provide the coreactant into the reaction chamber in vapor phase, and the assembly is constructed and arranged to provide the coreactant via the reactant injector system to the reaction chamber.

In some embodiments, the assembly further comprises a temperature controller for controlling the temperature of the reaction chamber. The temperature in the reaction chamber can be set to be between 50° ° C. and 200° ° C., such as 75° ° C. and 175° C., for example 100° C. and 150° C. as described in the above disclosure.

The disclosure is further explained by the following exemplary embodiments depicted in the drawings. The illustrations presented herein are not meant to be actual views of any particular material, structure, or device, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

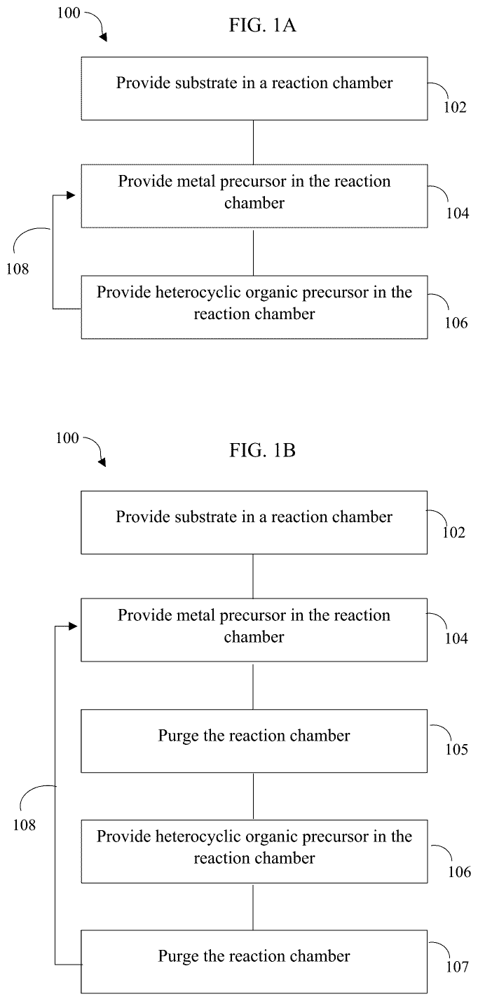

FIGS. 1A and 1B illustrate exemplary embodiments of a method 100 according to the current disclosure. Method 100 may be used to form an extreme ultraviolet (EUV) sensitive film on a substrate. The film can be used during a formation of a structure or a device, such as a structure and device described herein. However, unless otherwise noted, methods are not limited to such applications.

During step 102, a substrate is provided into a reaction chamber of a reactor. The reaction chamber can form part of an atomic layer deposition (ALD) or molecular layer deposition (MLD) reactor. The reaction chamber may be a single wafer reactor. Alternatively, the reactor may be a batch reactor. Various phases of method 100 can be performed within a single reaction chamber or they can be performed in multiple reactor chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, a reactor including the reaction chamber can be provided with a heater to activate the reactions by elevating the temperature of one or more of the substrate and/or the reactants and/or precursors.

During step 102, the substrate can be brought to a desired temperature and pressure for providing metal precursor in the reaction chamber 104 and/or for providing heterocyclic organic precursor in the reaction chamber 106. A temperature (e.g. of a substrate or a substrate support) within a reaction chamber can be, for example, from about 70° C. to about 130° C., or from about 80° ° C. to about 120° C. As a further example, a temperature within a reaction chamber can be from about 90° ° C. to about 110° C. Exemplary temperatures within the reaction chamber may be 70° ° C., 80° C., 90° C., 100° C., 110° ° C., 120° C., and 130° C.

A pressure within the reaction chamber can be less than 500 Torr, for example 400 Torr, 100 Torr, 50 Torr or 20 Torr, 5 Torr, 1 Torr or 0.1 Torr. Different pressure may be used for different process steps.

Metal precursor is provided in the reaction chamber containing the substrate 104. Without limiting the current disclosure to any specific theory, metal precursor may chemisorb on the substrate during providing metal precursor in the reaction chamber. The duration of providing metal precursor in the reaction chamber (metal precursor pulse time) may be, for example, 0.01 s, 0.5 s, 1 s, 1.5 s, 2 s, 2.5 s, 3 s, 3.5 s, 4 s, 4.5 s or 5 s. In some embodiments, the duration of providing metal precursor in the reaction chamber (metal precursor pulse time) may be more than 5 s or more than 10 s or about 20 s.

When heterocyclic organic precursor is provided in the reaction chamber 106, it may react with the chemisorbed metal precursor, or its derivate species, to form a EUV sensitive film. The duration of providing heterocyclic organic precursor in the reaction chamber (heterocyclic organic precursor pulse time) may be, for example 0.5 s, 1 s, 2 s, 3 s, 3.5 s, 4 s, 5 s, 6 s, 7 s, 8 s, 10 s, 12 s, 15 s, 30 s, 40 s, 50 s or 60 s. In some embodiments, the duration of providing heterocyclic organic precursor in the reaction chamber is be less than 15 s or less than 10 s or about 3 s.

In some embodiments, metal precursor may be heated before providing it into the reaction chamber. In some embodiments, the heterocyclic organic precursor may be heated before providing it to the reaction chamber. In some embodiments, the heterocyclic organic precursor may be kept at ambient temperature before providing it to the reaction chamber.

Steps 104 and 106, performed in any order, may form a deposition cycle, resulting in the deposition of a material comprising metal and organic chain. In some embodiments, the two steps of the deposition, namely providing the metal precursor and the heterocyclic organic precursor in the reaction chamber (104 and 106), may be repeated (loop 108). Such embodiments contain several deposition cycles. The thickness of the deposited material may be regulating by adjusting the number of deposition cycles. The deposition cycle (loop 108) may be repeated until a desired material thickness is achieved. For example about 50, 100, 150, 200, 250, 300, 400, 500, 600, 700, 800, 1,200 or 1,500 deposition cycles may be performed.

Depending on the deposition conditions, deposition cycle numbers etc., film of variable thickness may be deposited. For example, a film may have a thickness between approximately 0.2 nm and 60 nm, or between about 2 nm and 40 nm, or between about 0.5 nm and 25 nm, or between about 1 nm and 50 nm, or between about 10 nm and 60 nm. A film may have a thickness of, for example, approximately 0.2 nm, 0.3 nm, 0.5 nm, 1 nm, 1.5 nm, 2 nm, 2.5 nm, 3 nm, 3.5 nm, 4 nm, 4.5 nm, 5 nm, 6 nm, 8 nm, 10 nm, 15 nm, 20 nm, 25 nm, 30 nm, 35 nm, 40 nm, 50 nm, 70 nm, 85 nm or 100 nm. The desired thickness may be selected according to the application in question.

Metal precursor and heterocyclic organic precursor may be provided in the reaction chamber in separate steps (104 and 106). FIG. 1B illustrates an embodiment according to the current disclosure, where steps 104 and 106 are separated by purge steps 105 and 107. In such embodiments, a deposition cycle comprises one or more purge steps 105, 107. During purge steps, precursors can be temporally separated from each other by inert gases, such as argon (Ar), nitrogen (N₂) or helium (He) and/or a vacuum pressure. The separation of metal precursor and heterocyclic organic precursor may alternatively be spatial. The duration of the purge step after the metal precursor 105 may be, for example 0.1 s, 1 s, 2 s, 3 s, 3.5 s, 4 s, 5 s, 6 s, 7 s, 8 s, 10 s, 12 s, 15 s, 30 s, 40 s, 50 s or 60 s. The duration of the purge step after the heterocyclic organic precursor 107 may be, for example 5 s, 6 s, 7 s, 8 s, 10 s, 12 s, 15 s, 30 s, 40 s, 50 s, 60 s, 80 s, 100 s, or 120 s.

Purging the reaction chamber 103, 105 may prevent or mitigate gas-phase reactions between a metal precursor and a heterocyclic organic precursor, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a metal precursor and a heterocyclic organic precursor. Because in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

When performing the method 100, an EUV sensitive film is deposited onto the substrate. The deposition process may be a cyclical deposition process, and may include cyclical CVD, ALD, MLD or a hybrid cyclical CVD/MLD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of a metal precursor and a heterocyclic organic precursor. Such a process may be referred to as cyclical CVD. In some embodiments, a cyclical CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process. In accordance with further examples, a cyclical deposition process may comprise the continuous flow of one reactant or precursor and the periodic pulsing of the other chemical component into the reaction chamber. The temperature and/or pressure within a reaction chamber during step 104 can be the same or similar to any of the pressures and temperatures noted above in connection with step 102.

In some embodiments, the metal precursor is brought into contact with a substrate surface 104, excess metal precursor is partially or substantially completely removed by an inert gas or vacuum 105, and heterocyclic organic precursor is brought into contact with the substrate surface comprising metal precursor. Metal precursor may be brought in to contact with the substrate surface in one or more pulses 104. In other words, pulsing of the metal precursor 104 may be repeated. The metal precursor on the substrate surface may react with the heterocyclic organic precursor to form an EUV sensitive film. Also pulsing of the heterocyclic organic precursor 106 may be repeated. In some embodiments, heterocyclic organic precursor may be provided in the reaction chamber first 106. Thereafter, the reaction chamber may be purged 105 and metal precursor provided in the reaction chamber in one or more pulses 104.

For example, if an EUV sensitive film is deposited at a temperature between 50 and 200° C., and the deposition cycle (providing metal precursor and heterocyclic organic precursor, separated by purging) is repeated between 150 and 250 times, it may be possible to obtain a material with a thickness between approximately 2 nm and 40 nm, for example 20 nm or 30 nm.

FIG. 1C illustrates an exemplary embodiment of the method 100. In addition to the above disclosure for FIGS. 1A and 1B, the embodiment according to FIG. 1C discloses step 109 in which a coreactant is provided into the reaction chamber. Without limiting the current disclosure to any specific theory, coreactant may react with the metal precursor to optimize the surface functional groups that may facilitate the ring-opening reaction for the heterocyclic organic compound. The duration of providing coreactant in the reaction chamber (coreactant pulse time) may be, for example, 0.01 s, 0.5 s, 1 s, 1.5 s, 2 s, 2.5 s, 3 s, 3.5 s, 4 s, 4.5 s or 5 s. In some embodiments, the duration of providing coreactant in the reaction chamber (coreactant pulse time) is may be more than 5 s or more than 10 s or about 20 s. The temperature and/or pressure within a reaction chamber during step 109 can be the same or similar to any of the pressures and temperatures noted above in connection with step 102.

Step 109 can be performed either simultaneously with steps 104 and/or 106 or before or after steps 104 and/or 106. In some embodiments, the three steps of the deposition, namely providing the metal precursor, the heterocyclic organic precursor and the coreactant into the reaction chamber (104, 106 and 109), may be repeated (loop 108). Such embodiments contain several deposition cycles. The thickness of the deposited film may be regulating by adjusting the number of deposition cycles. The deposition cycle (loop 108) may be repeated until a desired film thickness is achieved. For example about 50, 100, 150, 200, 250, 300, 400, 500, 600, 700, 800, 1,200 or 1,500 deposition cycles may be performed.

FIG. 1C also illustrates that steps 106 and 109 are separated by a purge step and there is provided a purge step 110 after the reactant pulse. In one embodiment, the purge steps 105, 107 and 110 are optional and the deposition cycle may comprise one or more purge steps 105, 107, 110. During purge steps, precursors can be temporally separated from each other by inert gases, such as argon (Ar), nitrogen (N₂) or helium (He) and/or a vacuum pressure, i.e. by simply venting unused reactants and reaction products without providing any purge gas.

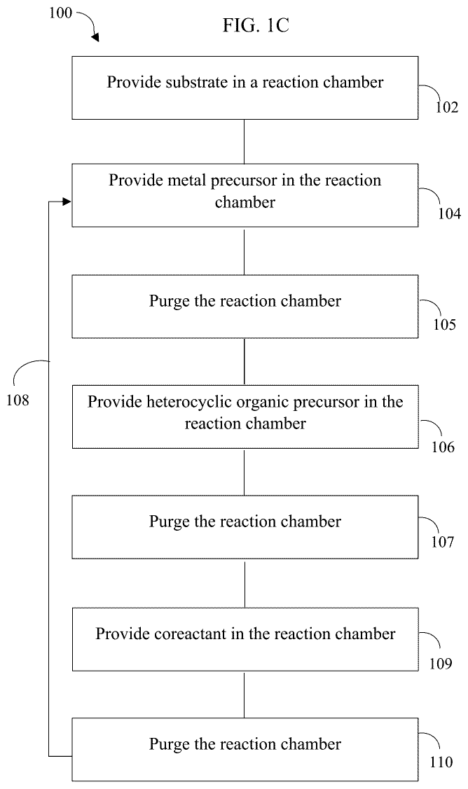

FIG. 2 illustrates a deposition assembly 200 according to the current disclosure in a schematic manner. Deposition assembly 200 can be used to perform a method as described herein and/or to form a structure or a device, or a portion thereof as described herein.

In the illustrated example, deposition assembly 200 includes one or more reaction chambers 202, a precursor injector system 201, a metal precursor vessel 204, heterocyclic organic precursor vessel 206, a purge gas source 208, an exhaust source 210, and a controller 212.

Reaction chamber 202 can include any suitable reaction chamber, such as an ALD, CVD or MLD reaction chamber.

The metal precursor vessel 204 can include a vessel and one or more metal precursors as described herein—alone or mixed with one or more carrier (e.g., inert) gases. Heterocyclic organic precursor vessel 206 can include a vessel and one or more heterocyclic organic precursors as described herein—alone or mixed with one or more carrier gases. Purge gas source 208 can include one or more inert gases as described herein. Although illustrated with three source vessels 204-208, deposition assembly 200 can include any suitable number of source vessels. Source vessels 204-208 can be coupled to reaction chamber 202 via lines 214-218, which can each include flow controllers, valves, heaters, and the like. In some embodiments, the metal precursor in the metal precursor vessel may be heated. In some embodiments, the vessel is heated so that the metal precursor reaches a temperature between about 60° ° C. and about 160° C., such as between about 100° C. and about 145° C., for example 85° C., 100° C., 110° C., 120° C., 130° C. or 140° C.

Exhaust source 210 can include one or more vacuum pumps.

Controller 212 includes electronic circuitry and software to selectively operate valves, manifolds, heaters, pumps and other components included in the deposition assembly 200. Such circuitry and components operate to introduce precursors and purge gases from the respective sources 204-208. Controller 212 can control timing of gas pulse sequences, temperature of the substrate and/or reaction chamber 202, pressure within the reaction chamber 202, and various other operations to provide proper operation of the deposition assembly 200. Controller 212 can include control software to electrically or pneumatically control valves to control flow of precursors and purge gases into and out of the reaction chamber 202. Controller 212 can include modules such as a software or hardware component, which performs certain tasks. A module may be configured to reside on the addressable storage medium of the control system and be configured to execute one or more processes.

Other configurations of deposition assembly 200 are possible, including different numbers and kinds of precursor and reactant sources and purge gas sources. Further, it will be appreciated that there are many arrangements of valves, conduits, precursor sources, and purge gas sources that may be used to accomplish the goal of selectively and in coordinated manner feeding gases into reaction chamber 202. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 200, substrates, such as semiconductor wafers (not illustrated), are transferred from, e.g., a substrate handling system to reaction chamber 202. Once substrate(s) are transferred to reaction chamber 202, one or more gases from gas sources 204-208, such as precursors, reactants, carrier gases, and/or purge gases, are introduced into reaction chamber 202.

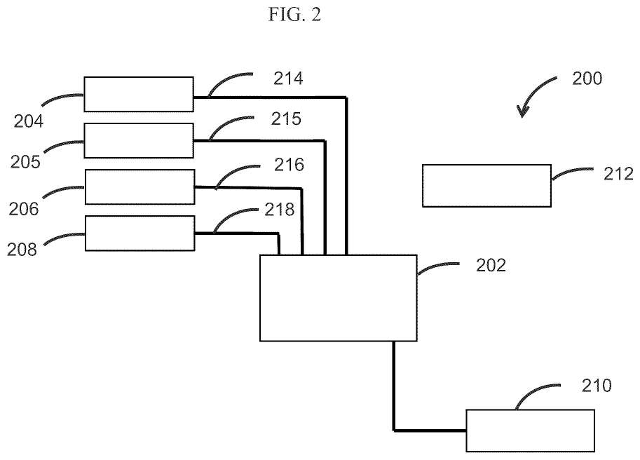

In an example, reference is made to FIG. 3, which schematically shows an embodiment of a method of forming an EUV sensitive film as described herein. In the embodiment shown, one or more deposition cycles are carried out. A deposition cycle comprises a first pulse and a second pulse. The first pulse comprises exposing the substate to TDMASn. The second pulse comprises exposing the substrate to maleic anhydride. An EUV sensitive film is formed. Selecting the number of deposition cycles allows controlling the thickness of the EUV-sensitive layer, with higher numbers of deposition cycles corresponding to thicker EUV-sensitive layers. Thus, an EUV sensitive film comprising an inorganic-organic hybrid polymer film is formed on the substrate. The substrate can then be exposed to EUV radiation through a photomask to form exposed and unexposed areas on the substrate. In the unexposed areas, the EUV sensitive film remains substantially untouched. In the exposed areas, the EUV sensitive film is at least partially decomposed under influence of the EUV radiation to form volatile reaction products such as CO₂, CₓH_{y}, NCₓH_{y} and optionally further forming organic residue or scum. In the current example the decomposed film is a film comprising SnOₓ. It shall be understood that “EUV radiation” can refer to electromagnetic radiation having a wavelength of at least 10 nm to at most 100 nm, or of at least 11 nm of at most 50 nm, or of at least 12 nm to at most 20 nm, or of at least 13 nm to at most 14 nm.

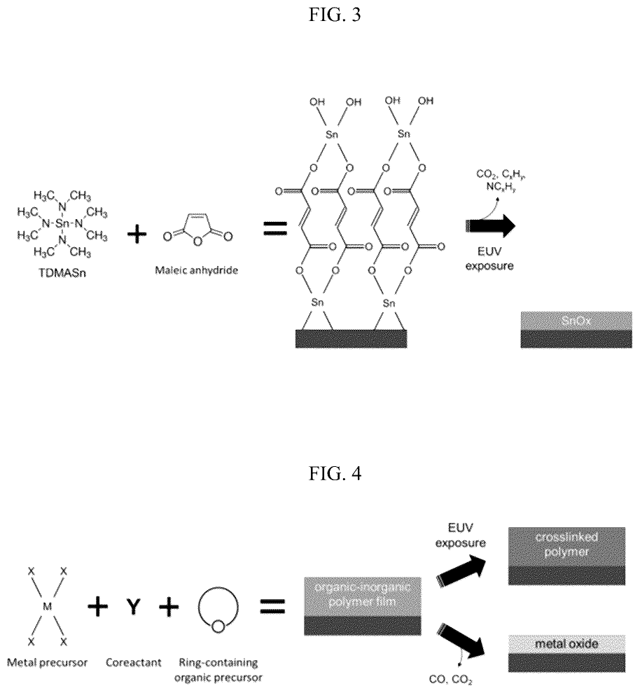

In another example, reference is made to FIG. 4, which schematically shows an embodiment of a method of forming an EUV sensitive film as described herein. In the embodiment shown, one or more deposition cycles are carried out. A deposition cycle comprises a first pulse, a second pulse and a third pulse the first pulse comprises exposing the substrate to a metal precursor. The second pulse comprises exposing the substrate to a coreactant. The third pulse comprises exposing the substrate to a ring-containing organic precursor, for example a heterocyclic organic precursor. An EUV sensitive film is formed. Selecting the number of deposition cycles allows controlling the thickness of the EUV-sensitive layer, with higher numbers of deposition cycles corresponding to thicker EUV-sensitive layers. Thus, an EUV sensitive film comprising an organic polymer film is formed on the substrate. The substrate can then be exposed to EUV radiation through a photomask to form exposed and unexposed areas on the substrate. In the unexposed areas, the EUV sensitive film remains substantially untouched. In the exposed areas, the EUV sensitive film is at least partially decomposed under influence of the EUV radiation to form volatile reaction products such as CO, CO₂, and optionally further forming organic residue or scum. In the current example the decomposed film is a film comprising metal oxide and the by-product is a crosslinked polymer.

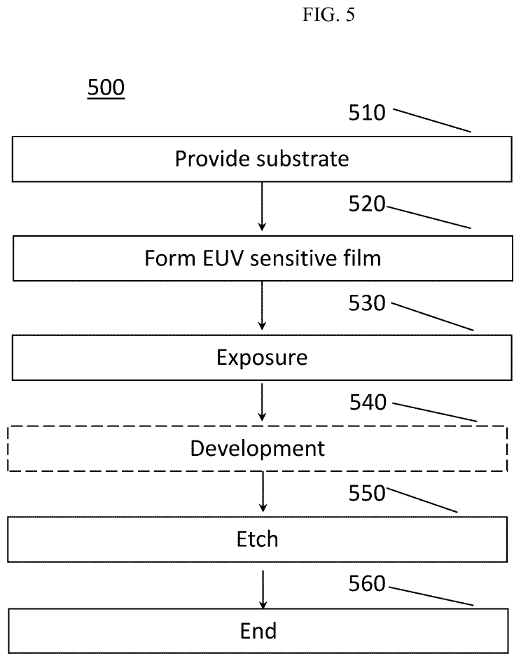

In a further example, reference is made to FIG. 5. FIG. 5 shows an exemplary embodiment of a method 500 of forming a pattern on a substrate. The method 500 comprises a step of providing a substrate 510. Then, an EUV sensitive film is formed on the substrate 520 by way of a method as described herein. The EUV sensitive film is then exposed 530 to EUV radiation, thus forming exposed areas and unexposed areas. After EUV exposure 530, the EUV sensitive film can optionally be developed 540 using resist development techniques which, as such, are known in the Art. Exemplary developers include aqueous solutions of tetramethylammonium hydroxide. It shall, however, be understood that a development step 540 does not necessarily have to be carried out since, in some embodiments, EUV-exposure results in removal of the EUV sensitive film in exposed areas. Even in such embodiments, substrate exposure to a developer solution can still be useful though, for example as a means for removing resist residues from exposed areas. The present exemplary embodiment further comprises an etching step 550 in which the substrate is exposed to an etchant. The etchant can advantageously etch a surface layer comprised in the substrate selectively vis-à-vis unexposed areas of the EUV sensitive film. It shall be understood that suitable etching chemistries are, as such, described in the Art, and include fluorine-based etching chemistries such as Ar plasmas employing a plasma gas comprising a fluorine-containing etchant such as SF₆, C₄F₈ or CF₄. After the etching step 550, a method according to the presently described embodiment ends 560. Thus, a surface layer comprised in a substrate can be patterned. The substrate can then be subjected to further processing steps, as needed.

The illustrations presented herein are not meant to be actual views of any particular material, structure, or device, but are merely idealized representations that are used to describe embodiments of the disclosure.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming an extreme ultraviolet (EUV) sensitive film on a substrate by a cyclic deposition process, the method comprising:
providing a substrate in a reactor chamber; and
executing a cyclical deposition process, the cyclical deposition process comprising the following steps i-ii:
i. providing a metal precursor into the reactor chamber in vapor phase; and
ii. providing a heterocyclic organic precursor into the reactor chamber in vapor phase;
to form a EUV sensitive film on a substrate.

2. The method according to claim 1, wherein the deposition process is molecular layer deposition.

3. The method according to claim 1, wherein the organic ring in the heterocyclic organic precursor is selected from the group consisting of cyclic carboxylic acid anhydride, cyclic carbonate, and cyclic azasilane.

4. The method according to claim 1, wherein the heterocyclic organic precursor comprises a carbon-carbon double bond or carbon-carbon single bond in the ring.

5. The method according to claim 1, wherein the heterocyclic organic precursor comprises maleic anhydride.

6. The method according to claim 1, wherein the metal precursor comprises a metal atom selected from the group consisting of Sn, Ti, Zn, Zr, Sb, Te, Ge, Al, and Hf.

7. The method according to claim 1, wherein the metal precursor comprises at least one ligand selected from the group consisting of halide, alkyl, alkoxide, alkylamido, and amidinate.

8. The method according to claim 1, wherein the process further comprises providing a coreactant into the reactor chamber in vapor phase.

9. The method according to claim 8, wherein the coreactant is chosen from the group consisting of water, ammonia, homobifunctional organic molecule, and heterobifunctional organic molecule.

10. The method according to claim 9, wherein the homobifunctional organic molecule and the heterobifunctional organic molecule comprise at least one molecule selected from the group consisting of alcohol, amine, thiol, carboxylic acid, and carboxylic acid halide.

11. The method according to claim 9, wherein the two functional groups in the homobifunctional organic molecule and heterobifunctional organic molecule are connected by an alkyl chain consisting of 1-8 carbon atoms.

12. The method according to claim 9, wherein the two functional groups in the homobifunctional organic molecule and heterobifunctional organic molecule are attached to a benzene ring.

13. The method according to claim 9, wherein the two functional groups in the homobifunctional organic molecule and heterobifunctional organic molecule are attached to separate carbon atoms on a cycloalkane comprising from 3 to 8 carbon atoms.

14. The method according to claim 1, wherein a pulse time of the metal precursor is 0.05 to 10 sec.

15. The method according to claim 1, wherein a purge time of the metal precursor is 0.1 to 120 sec.

16. The method according to claim 1 wherein a pulse time of the heterocyclic organic precursor is 0.1 to 30 sec.

17. The method according to claim 1, wherein a pulse time of the heterocyclic organic precursor is 1 to 240 sec.

18. The method according to claim 1, wherein the deposition pressure in the cyclical deposition process is 0.1 torr to 50 torr.

19. The method according to claim 1, wherein the deposition temperature in the cyclical deposition process is between 50 to 200° ° C.

20. A system comprising:
one or more reaction chambers constructed to hold a substrate;
a metal precursor vessel constructed and arranged to contain and evaporate a metal precursor;
a ring containing organic precursor vessel constructed and arranged to contain and evaporate a ring containing organic precursor; and
a controller, wherein the controller is configured to control gas flow of the metal precursor and the ring containing organic precursor into the one or more reaction chambers to form a film on a substrate comprised in the reaction chamber by the method according to claim 1.
